(19) United States
(12) Patent Application Publication
(10) Pub. No.: US 2026/0237424 A1
(43) Pub. Date: Aug. 13, 2026

(54) RECEIVER CIRCUIT, SEMICONDUCTOR MEMORY DEVICE, AND METHOD OF CONTROLLING SEMICONDUCTOR MEMORY DEVICE

(71) Applicant: Winbond Electronics Corp., Taichung City (TW)

(72) Inventor: Takahiko SATO, Yokohama (JP)

(73) Assignee: Winbond Electronics Corp., Taichung City (TW)

(21) Appl. No.: 19/404,772

(22) Filed: Dec. 1, 2025

(30) Foreign Application Priority Data
Feb. 12, 2025 (JP) 2025-020444

(51) Int. Cl. G11C 11/4093; G11C 11/4096

(52) U.S. Cl. CPC G11C 11/4093; G11C 11/4096

(57) ABSTRACT

The object of the present invention is to provide a receiving circuit, a semiconductor memory device, and a control method for the semiconductor memory device that can implement high-speed operation even when the amplitude of the input signal is large. The solution of the present invention is a receiving circuit (1), including: amplifier units (10a,10b) ,which amplify an input signal (CK_t) and are configured to operate with bias voltages (PBIAS,NBIAS) based on the voltage of the input signal (CK_t); and controller units (13a,13b) that suppress the bias voltages (PBIAS,NBIAS) from becoming a floating state while the input signal (CK_t) with an amplitude greater than a given value is input to the amplifier units (10a,10b).

### CROSS REFERENCE TO RELATED APPLICATIONS

This application claims priority of Japanese patent application No. 2025-020444, filed Feb. 12, 2025, the entirety of which is incorporated by reference herein.

### TECHNICAL FIELD

The present disclosure relates to a receiver circuit, a semiconductor memory device, and a method for controlling the same.

### BACKGROUND

In the conventional art (as disclosed in Japanese Unexamined Patent Application Publication No. 2001-103098, for example), a semiconductor memory device such as a Dynamic Random Access Memory (DRAM) includes a receiver circuit having an amplifier section for amplifying an externally input signal.

To enable the operation of the amplifier, a conventional receiver circuit is provided with a transistor for controlling a bias voltage, which is generated based on the voltage of the input signal. However, when an input signal having an amplitude that exceeds a predetermined value is supplied to the amplifier, the transistor-based amplifier may be turned off, causing the bias voltage to enter a floating state. In such a situation, it becomes difficult to properly pull-up or pull-down the output signal of the amplifier. As a result, the amplitude of the output signal cannot be constrained within a desired range. Consequently, the time required to invert the logic state of the output signal increases, which can make it difficult to achieve high-speed operation of the semiconductor device.

### BRIEF SUMMARY

To address the problems described above, an embodiment of the present disclosure provides a receiver circuit. The receiver circuit comprises an amplifier and a controller. The amplifier is configured to amplify an input signal and to operate based on a bias voltage that is dependent on the voltage of the input signal. The controller is configured to prevent the bias voltage from entering a floating state when an input signal with an amplitude that exceeds a predetermined value is supplied to the amplifier.

According to the present disclosure, because the controller prevents the bias voltage from entering a floating state when an input signal with a large amplitude is received, the output signal of the amplifier can be properly pulled up or pulled down. This allows the amplitude of the output signal to be constrained within a desired range. Consequently, the time required to invert the logic state of the output signal is shortened, enabling high-speed operation of the semiconductor device even when the amplitude of the input signal is large.

In another aspect, the present disclosure provides a semiconductor memory device that includes the receiver circuit described above.

In yet another aspect, the present disclosure provides a method for controlling a semiconductor memory device. The receiver circuit of the semiconductor memory device comprises an amplifier and a controller. The amplifier amplifies an input signal and operates based on a bias voltage derived from the input signal's voltage. The method, executed by the controller, comprises a step of preventing the bias voltage from entering a floating state when an input signal that has an amplitude that exceeds the predetermined value is supplied to the amplifier.

Accordingly, the receiver circuit, the semiconductor memory device, and the method of controlling the semiconductor memory device of the present disclosure can achieve high-speed operation even in cases where the amplitude of the input signal is large.

### BRIEF DESCRIPTION OF THE DRAWINGS

The present disclosure can be more fully understood by reading the subsequent detailed description and examples with references made to the accompanying drawings, wherein:

FIG. 1 is a schematic diagram illustrating a configuration of a receiver circuit according to an embodiment of the present disclosure.

FIG. 2 is a schematic diagram illustrating a configuration of a voltage generation unit.

FIG. 3 is a schematic diagram illustrating a configuration of the receiver circuit when a clock signal and a complementary clock signal are input.

In FIG. 4, (a) is a timing chart illustrating a temporal transition of an output signal of an amplifier section according to a comparative example (C.E) and an output signal of an amplifier section according to an embodiment (Ex.) when a complementary clock signal is input; and (b) is a timing chart illustrating a temporal transition of a bias voltage according to the comparative example and a bias voltage according to the embodiment when a complementary clock signal is input.

### DETAILED DESCRIPTION

The following description is made for the purpose of illustrating the general principles of the disclosure and should not be taken in a limiting sense. The scope of the disclosure is best determined by reference to the appended claims.

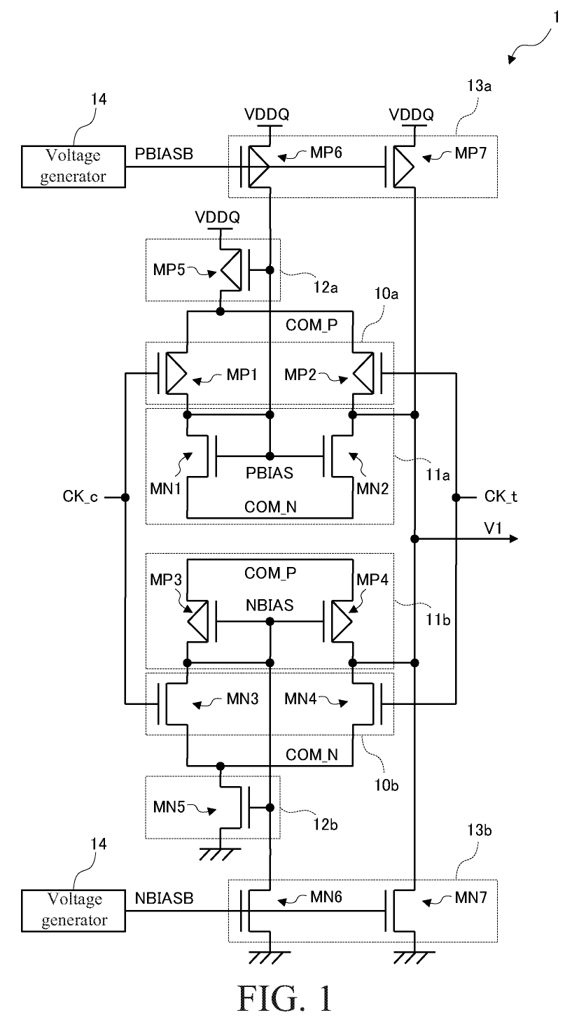

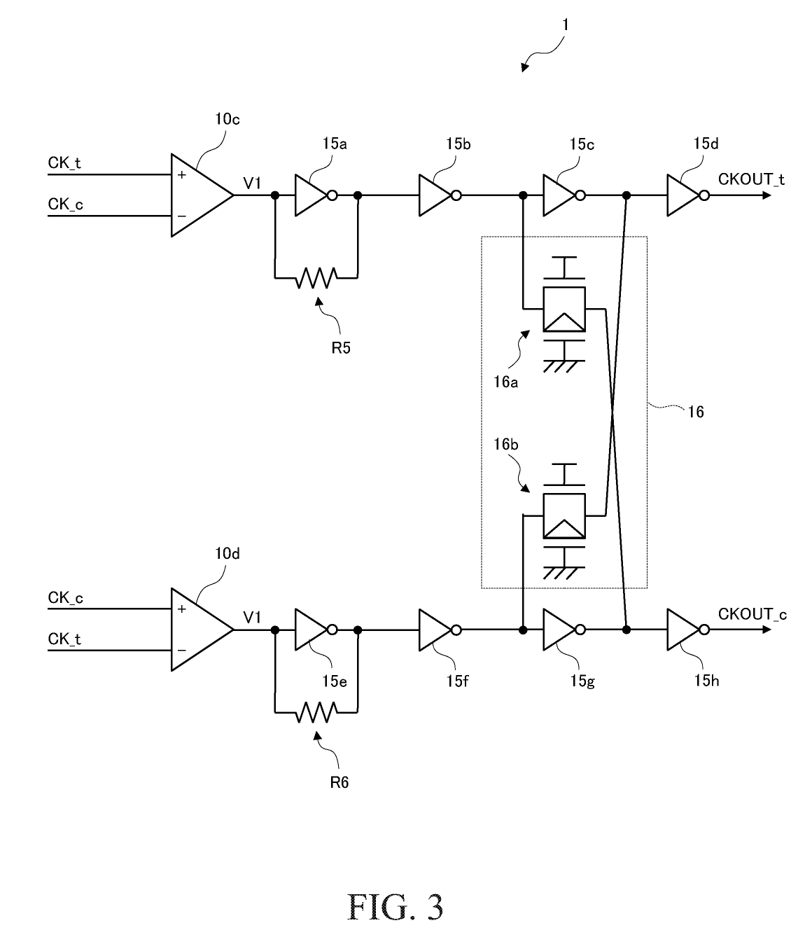

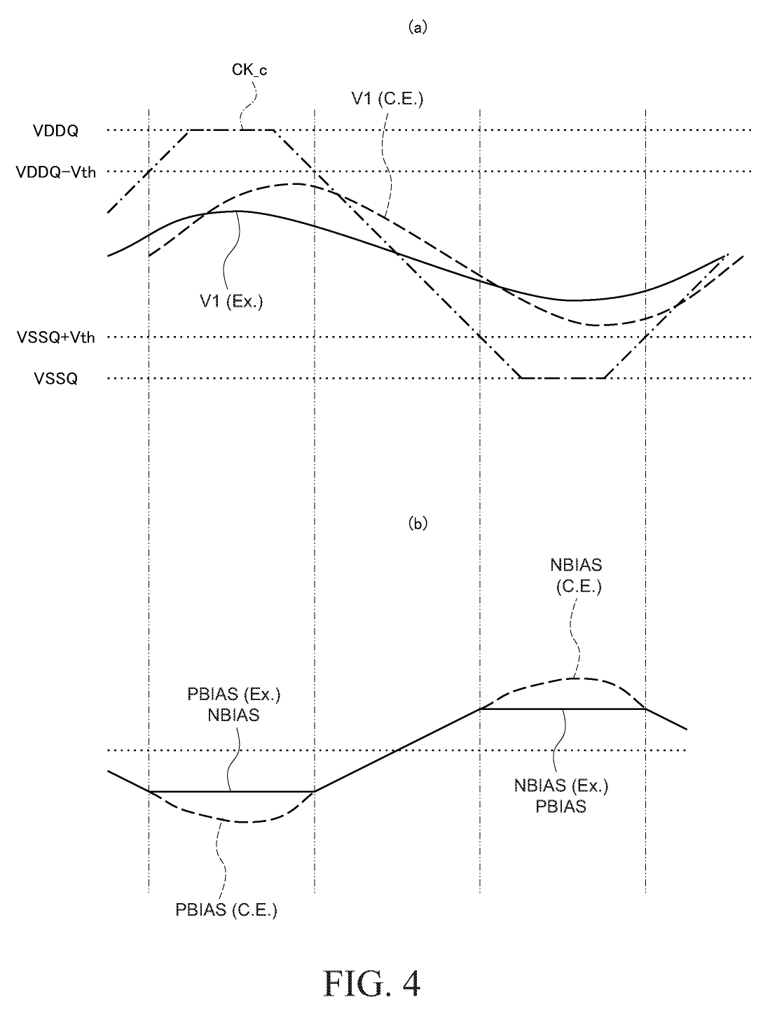

FIG. 1 is a schematic block diagram illustrating an exemplary structure of a receiver circuit according to an embodiment of the present disclosure. The receiver circuit 1 according to an embodiment of the present disclosure is provided in a semiconductor memory device (e.g., a dynamic random access memory) and is configured to receive signals input to the semiconductor memory device from an external device. In this embodiment, the receiver circuit 1 comprises amplifiers 10a and 10b; current mirror sections 11a and 11b serving as loads for the amplifiers 10a and 10b; bias transistors 12a and 12b; controllers 13a and 13b; a voltage generator 14; a plurality of inverter circuits 15a-15h (as shown in FIG. 3); and an adjustment circuit 16 (as shown in FIG. 3). Furthermore, as shown in FIG. 1, the amplifiers 10a and 10b, the current mirror sections 11a and 11b, the bias transistors 12a and 12b, and the controllers 13a and 13b are respectively composed of any of a plurality of P-type transistors MP1-MP7 and a plurality of N-type transistors MN1-MN7. For simplicity of explanation, other conventional components of the semiconductor memory device (e.g., a memory cell array, a power supply circuit, a clock generator) are not illustrated herein.

In this embodiment, the amplifiers 10a and 10b are differential amplifiers, wherein an input clock signal CK_t is input to one input terminal, and a complementary clock signal CK_c of the input clock signal CK_t is input to another input terminal. Therefore, in the amplifiers 10a and 10b, common-mode noise can be easily removed by amplifying the difference between the voltage of the clock signal CK_t and the voltage of the complementary clock signal CK_c. Furthermore, the amplifiers 10a and 10b amplify the voltage difference between the clock signal CK_t and the complementary clock signal CK_c and output this amplified signal as an output signal V1. In other embodiments, the amplifiers 10a and 10b may be other types of amplifiers.

Here, the amplifier 10a comprises a pair of P-type transistors MP1 and MP2. The complementary clock signal CK_c is input to a gate of the P-type transistor MP1, and the clock signal CK_t is input to a gate of the P-type transistor MP2. Sources of the P-type transistors MP1 and MP2 are connected together. The amplifier section 10a is an example of a "first differential amplifier" of the present disclosure.

Furthermore, the amplifier 10b is connected in parallel with the amplifier 10a and comprises a pair of N-type transistors MN3 and MN4. The complementary clock signal CK_c is input to a gate of the N-type transistor MN3, and the clock signal CK_t is input to a gate of the N-type transistor MN4. Sources of the N-type transistors MN3 and MN4 are connected together. The amplifier section 10b is an example of a "second differential amplifier" of the present disclosure.

The current mirror section 11a comprises a pair of N-type transistors MN1 and MN2. A drain of the N-type transistor MN1 is connected to a drain of the P-type transistor MP1 of the amplifier 10a, and a gate of the N-type transistor MN1 is connected to a bias voltage PBIAS. The gate of the N-type transistor MN1 is also diode-connected to the drain of the N-type transistor MN1. A drain of the N-type transistor MN2 is connected to a drain of the P-type transistor MP2 of the amplifier 10a and to the output signal V1 of the amplifiers 10a and 10b. A gate of the N-type transistor MN2 is connected to the bias voltage PBIAS. Sources of the N-type transistors MN1 and MN2 are connected together.

The current mirror section 11b comprises a pair of P-type transistors MP3 and MP4. A drain of the P-type transistor MP3 is connected to a drain of the N-type transistor MN3 of the amplifier 10b, and a gate of the P-type transistor MP3 is connected to a bias voltage NBIAS. The gate of the P-type transistor MP3 is also diode-connected to the drain of the P-type transistor MP3. A drain of the P-type transistor MP4 is connected to a drain of the N-type transistor MN4 of the amplifier 10b and to the output signal V1 of the amplifiers 10a and 10b. A gate of the P-type transistor MP4 is connected to the bias voltage NBIAS. Sources of the P-type transistors MP3 and MP4 are connected together.

The bias transistor 12a comprises a P-type transistor MP5 and is configured to control the bias voltage PBIAS. A source of the P-type transistor MP5 is connected to a high power supply voltage (e.g., an input/output voltage VDDQ), and a drain of the P-type transistor MP5 is connected to the sources of the P-type transistors MP1 and MP2 of the amplifier 10a. A gate of the P-type transistor MP5 is connected to the bias voltage PBIAS.

The bias transistor 12b comprises an N-type transistor MN5 and is configured to control the bias voltage NBIAS. A source of the N-type transistor MN5 is connected to a low power supply voltage (e.g., a ground voltage VSSQ), and a drain of the N-type transistor MN5 is connected to the sources of the N-type transistors MN3 and MN4 of the amplifier 10b. A gate of the N-type transistor MN5 is connected to the bias voltage NBIAS.

When an input signal (in this case, the clock signal CK_t and the complementary clock signal CK_c) having an amplitude exceeding a predetermined value is input to the amplifiers 10a and 10b, the controllers 13a and 13b prevent the bias voltages PBIAS and NBIAS from entering a floating state.

The controllers 13a and 13b are configured to operate based on power supply voltages (in this case, voltages PBIASB and NBIASB to be described later) that are different from the voltages of the input signals (clock signal CK_t and complementary clock signal CK_c). Accordingly, the controllers 13a and 13b can operate independently of the input signals, thereby allowing the controllers 13a and 13b to reliably prevent the bias voltages PBIAS and NBIAS from entering a floating state.

Furthermore, the operating current of the controllers 13a and 13b may be greater than the minimum operating current and less than the maximum operating current of the portions controlled by the bias voltages PBIAS and NBIAS (in this embodiment, the amplifiers 10a and 10b, the current mirror sections 11a and 11b, and the bias transistors 12a and 12b). With this configuration, the bias voltages PBIAS and NBIAS can be prevented from floating while suppressing any adverse effects on the operation of the amplifiers 10a and 10b.

The controller 13a comprises P-type transistors MP6 and MP7. The source of the P-type transistor MP6 is connected to the high power supply voltage (voltage VDDQ), and a drain of the P-type transistor MP6 is connected to the diode-connected side of the current mirror section 11a and to the gate of the bias transistor 12a (i.e., connected to the bias voltage PBIAS). A gate of the P-type transistor MP6 is connected to the voltage PBIASB generated by the voltage generator 14. The P-type transistor MP6 is an example of a "first transistor" of the present disclosure.

A source of the P-type transistor MP7 is connected to the voltage VDDQ, and a drain of the P-type transistor MP7 is connected to the output signal V1 of the amplifiers 10a and 10b. A gate of the P-type transistor MP7 is connected to the voltage PBIASB generated by the voltage generator 14. The P-type transistor MP7 is an example of a "second transistor" of the present disclosure.

The controller 13b comprises N-type transistors MN6 and MN7. A source of the N-type transistor MN6 is connected to the low power supply voltage (voltage VSSQ), and a drain of the N-type transistor MN6 is connected to the diode-connected side of the current mirror section 11b and to the gate of the bias transistor 12b (i.e., connected to the bias voltage NBIAS). A gate of the N-type transistor MN6 is connected to the voltage NBIASB generated by the voltage generator 14. The N-type transistor MN6 is an example of a "first transistor" of the present disclosure.

A source of the N-type transistor MN7 is connected to the low power supply voltage (voltage VSSQ), and a drain of the N-type transistor MN7 is connected to the output signal V1 of the amplifiers 10a and 10b. A gate of the N-type transistor MN7 is connected to the voltage NBIASB generated by the voltage generator 14. The N-type transistor MN7 is an example of a "second transistor" of the present disclosure.

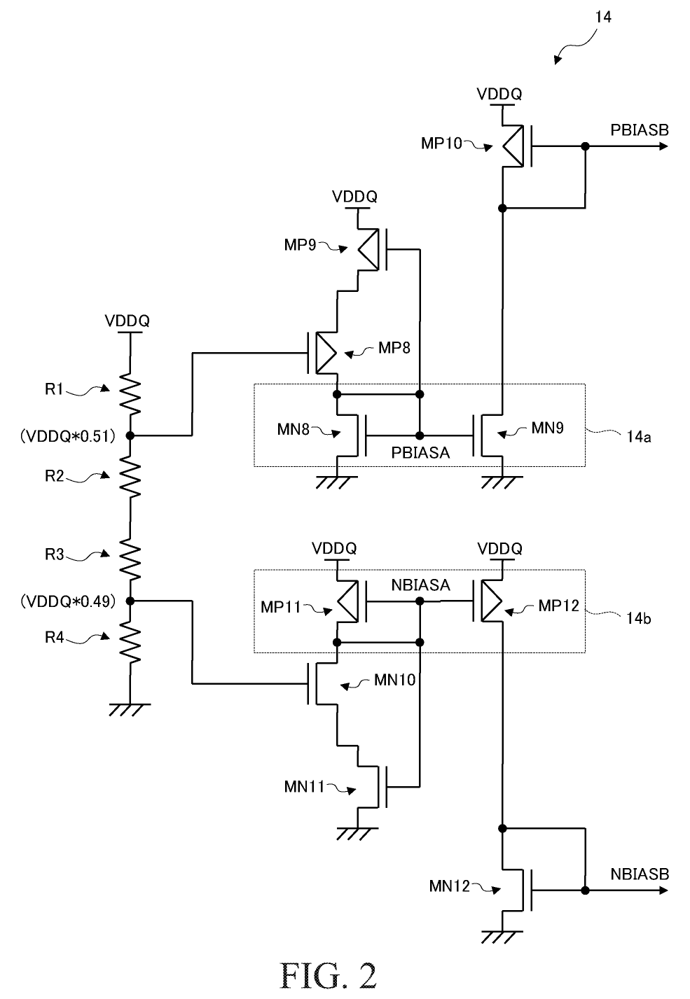

The configuration of the voltage generator 14 in this embodiment will be described with reference to FIG. 2. The voltage generator 14 is configured to generate power supply voltages (voltages PBIASB and NBIASB) that are different from the voltages of the input signals (clock signal CK_t and complementary clock signal CK_c). As shown in FIG. 2, the voltage generator 14 comprises a plurality of (e.g., four) resistors R1-R4, a plurality of P-type transistors MP8-MP12, and a plurality of N-type transistors MN8-MN12.

Here, the voltage generator 14 may also comprise at least one current mirror section 14a and 14b. Therefore, the output current of the voltage generator 14 can be kept constant.

The plurality of resistors R1-R4 are connected in series between the high power supply voltage (voltage VDDQ) and the low power supply voltage (voltage VSSQ).

A gate of the P-type transistor MP8 is connected to a node between the resistor R1 and the resistor R2, and a drain of the P-type transistor MP8 is connected to the current mirror section 14a. Furthermore, a source of the P-type transistor MP9 is connected to the high power supply voltage (voltage VDDQ), and a drain of the P-type transistor MP9 is connected to a source of the P-type transistor MP8. Furthermore, a gate of the P-type transistor MP9 is connected to the bias voltage PBIASA.

The current mirror section 14a comprises a pair of N-type transistors MN8 and MN9. A drain of the N-type transistor MN8 is connected to the drain of the P-type transistor MP8. The gate of the N-type transistor MN8 is connected to the bias voltage PBIASA and is diode-connected to the drain of the N-type transistor MN8. A drain of the N-type transistor MN9 is connected to a drain of the P-type transistor MP10, and a gate of the N-type transistor MN9 is connected to the bias voltage PBIASA. Sources of the N-type transistors MN8 and MN9 are connected to the low power supply voltage (voltage VSSQ).

A source of the P-type transistor MP10 is connected to the high power supply voltage (voltage VDDQ), and a gate of the P-type transistor MP10 is connected to an output voltage (voltage PBIASB) of the voltage generator 14. The gate of the P-type transistor MP10 is also diode-connected to the drain of the P-type transistor MP10.

A gate of the N-type transistor MN10 is connected to a node between the resistor R3 and the resistor R4, and a drain of the N-type transistor MN10 is connected to the current mirror section 14b. Furthermore, a source of the N-type transistor MN11 is connected to the low power supply voltage (voltage VSSQ), and a drain of the N-type transistor MN11 is connected to a source of the N-type transistor MN10. Furthermore, a gate of the N-type transistor MN11 is connected to the bias voltage NBIASA.

The current mirror section 14b comprises a pair of P-type transistors MP11 and MP12. A drain of the P-type transistor MP11 is connected to the drain of the N-type transistor MN10. The gate of the P-type transistor MP11 is connected to the bias voltage NBIASA and is diode-connected to the drain of the P-type transistor MP11. A drain of the P-type transistor MP12 is connected to a drain of the N-type transistor MN12, and a gate of the P-type transistor MP12 is connected to the bias voltage NBIASA. Sources of the P-type transistors MP11 and MP12 are connected to the high power supply voltage (voltage VDDQ).

A source of the N-type transistor MN12 is connected to the low power supply voltage (voltage VSSQ), and a gate of the N-type transistor MN12 is connected to an output voltage (voltage NBIASB) of the voltage generator 14. The gate of the N-type transistor MN12 is also diode-connected to the drain of the N-type transistor MN12.

The voltage generator 14 configured as described above generates the bias voltage PBIASA based on the voltage at the node between the resistor R1 and the resistor R2, and the bias voltage PBIASA is converted to the voltage PBIASB through the current mirror section 14a. Here, as will be described later, when the voltage of the complementary clock signal CK_c reaches the voltage VDDQ, the P-type transistor MP1 of the amplifier 10a enters an OFF state. To prevent the bias voltage PBIAS from entering a floating state, the voltage at the node between the resistor R1 and the resistor R2 used to generate the bias voltage PBIASA may be set to a predetermined value (e.g., 0.51×VDDQ, which is a value higher than VDDQ/2).

Similarly, when the voltage of the complementary clock signal CK_c reaches the voltage VSSQ, the N-type transistor MN3 of the amplifier 10b enters an OFF state. To prevent the bias voltage NBIAS from entering a floating state, the voltage at the node between the resistor R3 and the resistor R4 used to generate the bias voltage NBIASA may be set to a predetermined value (e.g., 0.49×VDDQ, which is a value lower than VDDQ/2).

Furthermore, to ensure the normal operation of the amplifiers 10a and 10b, the output current of the current mirror sections 14a and 14b (i.e., the operating current of the controllers 13a and 13b) may also be set to be less than the maximum operating current of the portions controlled by the bias voltages PBIAS and NBIAS (in this embodiment, the amplifiers 10a and 10b, the current mirror sections 11a and 11b, and the bias transistors 12a and 12b) (e.g., the output current value of the amplifiers 10a and 10b). In addition, as will be described later, to prevent the bias voltage PBIAS from saturating to a voltage COM_N and the bias voltage NBIAS from saturating to a voltage COM_P due to leakage current, the output current of the current mirror sections 14a and 14b (i.e., the operating current of the controllers 13a and 13b) may also be set to be greater than the minimum operating current of the portions controlled by the bias voltages PBIAS and NBIAS (e.g., the leakage current value of the current mirror sections 11a and 11b). The output current of the current mirror sections 14a and 14b can be set by arbitrarily setting the current mirror ratio of the current mirror sections 14a and 14b.

Furthermore, the voltage generator 14 may be configured to generate the voltages PBIASB and NBIASB during a predetermined period. This can reduce the power consumption of the receiver circuit 1 compared to a case where the voltages PBIASB and NBIASB are constantly generated. For example, the voltage generator 14 may generate the voltages PBIASB and NBIASB for a given period after the power-on sequence of the semiconductor memory device is completed. The voltage generator 14 may also generate the voltages PBIASB and NBIASB while a given generation instruction signal (not shown) is asserted. The generation instruction signal may be generated by a circuit other than the receiver circuit 1. In the case of a DRAM, for example, generating the voltages PBIASB and NBIASB while the Clock Enable (CKE) terminal is active can reduce power consumption during power-down. Moreover, by setting the aforementioned predetermined period as the recovery time from power-down, the desired voltages PBIASB and NBIASB are generated after the power-down period ends, allowing for more accurate input reception.

FIG. 3 shows an exemplary configuration for when the clock signal CK_t and the complementary clock signal CK_c are input to the receiver circuit 1. Here, FIG. 3 shows a simplified representation of amplifiers 10c and 10d, and each of the amplifiers 10c and 10d has the same configuration as the amplifiers 10a and 10b. For simplicity, other components connected to the amplifiers 10c and 10d in FIG. 1 (the current mirror sections 11a and 11b, the bias transistors 12a and 12b, the controllers 13a and 13b, and the voltage generator 14) are omitted in FIG. 3.

The clock signal CK_t is input to one input terminal (+ terminal) of the amplifier 10c, and the complementary clock signal CK_c is input to the other input terminal (- terminal). Furthermore, the complementary clock signal CK_c is input to one input terminal (+ terminal) of the amplifier 10d, and the clock signal CK_t is input to the other input terminal (- terminal). The amplifier section 10c is an example of a "third differential amplifier" of the present disclosure, and the amplifier section 10d is an example of a "fourth differential amplifier" of the present disclosure.

A plurality of (four in this example) inverter circuits 15a-15d are connected in series to an output terminal of the amplifier 10c. The inverter circuit 15a receives the output signal V1 of the amplifier 10c. Furthermore, the receiver circuit 1 is provided with a resistor R5 connected in parallel with the inverter circuit 15a. One end of the resistor R5 is connected to an output of the inverter circuit 15a, and the other end of the resistor R5 is connected to an input of the inverter circuit 15a. Therefore, the output signal of the inverter circuit 15a can be added as a feedback signal to the output signal V1 of the amplifier 10c. By the configuration of the inverter circuits 15b-15d, the amplitude of the output waveform can be shaped to a predetermined level (e.g., VDDQ/VSSQ). Here, the inverter circuit 15a is an example of a "logic inverting circuit" of the present disclosure, and the other inverter circuits 15b, 15c, and 15d are an example of "one or more other logic inverting circuits" of the present disclosure.

Furthermore, a plurality of (four in this example) inverter circuits 15e-15h are connected in series to an output terminal of the amplifier 10d. The inverter circuit 15e receives the output signal V1 of the amplifier 10d. The receiver circuit 1 is also provided with a resistor R6 connected in parallel with the inverter circuit 15e. One end of the resistor R6 is connected to an output of the inverter circuit 15e, and the other end of the resistor R6 is connected to an input of the inverter circuit 15e. Therefore, the output signal of the inverter circuit 15e can be added as a feedback signal to the output signal V1 of the amplifier 10d. By the configuration of the inverter circuits 15f-15h, the amplitude of the output waveform can be shaped to a predetermined level (e.g., VDDQ/VSSQ). Here, the inverter circuit 15e is an example of a "logic inverting circuit" of the present disclosure, and the other inverter circuits 15f, 15g, and 15h are an example of "one or more other logic inverting circuits" of the present disclosure.

The adjustment circuit 16 is configured to suppress errors in the output timing of each output signal V1 from the amplifiers 10c and 10d. Therefore, the output timing of the output clock signal CKOUT_t and the output complementary clock signal CKOUT_c from the receiver circuit 1 can be made consistent.

The adjustment circuit 16 comprises a plurality of (two in this example) transmission transistors 16a and 16b. The transmission transistor 16a is connected between a node between the inverter circuit 15b and the inverter circuit 15c, and a node between the inverter circuit 15g and the inverter circuit 15h. The transmission transistor 16b is connected between a node between the inverter circuit 15c and the inverter circuit 15d, and a node between the inverter circuit 15f and the inverter circuit 15g.

By providing the adjustment circuit 16 configured as described above, the output timing of the output clock signal CKOUT_t and the output complementary clock signal CKOUT_c from the receiver circuit 1 can be made consistent.

The operation of the receiver circuit 1 in this embodiment will be described with reference to FIG. 4. (a) of FIG. 4 is a schematic timing chart showing the time progression of the output signal V1 of the amplifiers 10a and 10b for a comparative example and for the present embodiment when the complementary clock signal CK_c is input. (b) of FIG. 4 is a schematic timing chart showing the time progression of the bias voltages PBIAS and NBIAS for the comparative example and for the present embodiment when the complementary clock signal CK_c is input. Here, a receiver circuit that does not include the controllers 13a and 13b and the voltage generator 14 in the receiver circuit 1 shown in FIG. 1 will be described as a comparative example.

In the receiver circuit of the comparative example, when the amplitude of the complementary clock signal CK_c is small (specifically, when the magnitude of the amplitude is between the voltage VSSQ+Vth and the voltage VDDQ-Vth, where Vth represents the threshold voltage of each of the transistors MP1, MP2, MN3, and MN4 of each of the amplifiers 10a and 10b), the transistors MP1, MP2, MN3, and MN4 of the amplifiers 10a and 10b that receive the complementary clock signal CK_c and its inverted clock signal CK_t are not fully turned on or off. Therefore, the bias voltages PBIAS and NBIAS can be generated stably, and each of the amplifiers 10a and 10b can generate an output signal V1 with a small amplitude.

Here, when the amplitude of the complementary clock signal CK_c becomes large (e.g., when the voltage of the complementary clock signal CK_c reaches the voltage VSSQ as shown on the right side at (a) of FIG. 4), the N-type transistor MN3 of the amplifier 10b that receives the complementary clock signal CK_c is turned off. In this case, the bias voltage NBIAS enters a floating state, and it is difficult to control the bias voltage NBIAS by the voltage dropped from the voltage COM_P on the source side of each of the P-type transistors MP3 and MP4 of the current mirror section 11b through the P-type transistor MP3. Therefore, as shown on the right side at (b) of FIG. 4, it is considered that the bias voltage NBIAS gradually rises toward the voltage COM_P due to the leakage current of the P-type transistor MP4. In this situation, since the clock signal CK_t has reached the voltage VDDQ, it is considered that the pull-down function for the output signal V1 in the N-type transistor MN4 of the amplifier 10b operates more strongly than expected.

Furthermore, when the clock signal CK_t reaches the voltage VDDQ, the P-type transistor MP2 of the amplifier 10a is turned off, and the pull-up function for the output signal V1 stops. Since the pull-down function for the output signal V1 in the amplifier 10b operates more strongly, the amplitude of the output signal V1 becomes large. Moreover, as shown on the left side at (a) of FIG. 4, when the voltage of the complementary clock signal CK_c reaches the voltage VDDQ, the pull-down function for the output signal V1 in the amplifier 10a stops. Since the pull-up function for the output signal V1 in the amplifier 10b operates more strongly, the amplitude of the output signal V1 becomes large. As a result, the time required to invert the logic state of the output signal V1 becomes longer, which may reduce the operating speed of the semiconductor memory device.

On the other hand, in the receiver circuit 1 according to the present embodiment, the problems of the comparative example described above are solved because the controllers 13a and 13b and the voltage generator 14 are provided. For example, when the voltage of the complementary clock signal CK_c reaches the voltage VSSQ, the N-type transistor MN3 of the amplifier 10b that receives the complementary clock signal CK_c is turned off. However, because the N-type transistor MN6 of the controller 13b supplies current to pull down the bias voltage NBIAS, the rise of the bias voltage NBIAS toward the voltage COM_P can be suppressed. In this situation, when the clock signal CK_t reaches the voltage VDDQ, the P-type transistor MP2 of the amplifier 10a is turned off. However, because the P-type transistor MP6 of the controller 13a supplies current to pull up the bias voltage PBIAS, the fall of the bias voltage PBIAS toward a voltage COM_N can be suppressed.

Therefore, as shown in (b) of FIG. 4, compared to the receiver circuit of the comparative example, the receiver circuit 1 of the present embodiment can suppress the variation in the bias voltages PBIAS and NBIAS. Furthermore, as shown in (a) of FIG. 4, the variation in the output signal V1 can be suppressed. Accordingly, because the time required to invert the logic state of the output signal V1 can be shortened, the receiver circuit 1 of the present embodiment can achieve high-speed operation of the semiconductor memory device even when the amplitude of the input signals (clock signal CK_t, complementary clock signal CK_c) is large.

As described above, according to the receiver circuit 1, the semiconductor memory device, and the control method thereof of the present embodiment, when an input signal (clock signal CK_t, complementary clock signal CK_c) having an amplitude exceeding a predetermined value is input to the amplifiers 10a and 10b, the bias voltages PBIAS and NBIAS are prevented from entering a floating state. This allows the pull-up/pull-down processing of the output signal V1 of the amplifiers 10a and 10b to be performed properly, and the amplitude of the output signal V1 can be suppressed within a desired range. Consequently, since the time required to invert the logic state of the output signal V1 can be shortened, high-speed operation of the semiconductor memory device can be achieved even when the amplitude of the input signals (clock signal CK_t, complementary clock signal CK_c) is large.

The embodiments described above are intended to be illustrative and not limiting. The present disclosure is not limited to these examples. Accordingly, any and all modifications, variations, or equivalent arrangements that fall within the spirit and scope of the present disclosure should be considered within the scope of the claims.

For example, in the above embodiments, the case where the clock signal CK_t and the complementary clock signal CK_c are input to the amplifiers 10a and 10b was described as an example, but the present disclosure is not limited to this case. For example, the input signal may also be a command signal, an address signal, or the like. When a command signal, an address signal, or the like is input to one input terminal of the amplifiers 10a and 10b, a predetermined reference signal may be input to the other input terminal of the amplifiers 10a and 10b. Here, taking the case where the semiconductor memory device conforms to the DDR4 SDRAM specification as an example, the voltage of the predetermined reference signal (e.g., VREF) may be half of the voltage VDDQ (i.e., VDDQ/2). In this case, similar to the above embodiments, high-speed operation of the semiconductor memory device can be achieved even when the amplitude of the input signal (command signal, address signal, etc.) is large.

Furthermore, in the above embodiments, the case where the semiconductor memory device is a DRAM was described as an example, but the present disclosure is not limited to this case. For example, the semiconductor memory device may be a static random access memory, a pseudo static random access memory, a flash memory, or another semiconductor memory device.

Each configuration of the amplifiers 10a and 10b, the current mirror sections 11a and 11b, the bias voltage transistors 12a and 12b, and the controllers 13a and 13b shown in FIG. 1; the voltage generator 14 shown in FIG. 2; and the adjustment circuit 16 shown in FIG. 3 is an example, and may be appropriately modified, and well-known configurations or various other structures may be adopted.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A receiver circuit, comprising:
an amplifier configured to amplify an input signal and to operate based on a bias voltage that is dependent on a voltage of the input signal; and
a controller configured to, when the input signal having an amplitude exceeding a predetermined value is supplied to the amplifier, prevent the bias voltage from entering a floating state.

2. The receiver circuit of claim 1, wherein the controller is configured to operate based on a power supply voltage that is different from the voltage of the input signal.

3. The receiver circuit of claim 2, wherein an operating current of the controller is greater than a minimum operating current of a portion controlled by the bias voltage and is less than a maximum operating current of the portion controlled by the bias voltage.

4. The receiver circuit of claim 2, further comprising:
a current mirror section serving as a load for the amplifier; and
a bias transistor configured to control the bias voltage;
wherein the controller comprises:
a first transistor, wherein a gate of the first transistor is connected to the power supply voltage, and wherein the first transistor is connected to a diode-connected side of the current mirror section and to a gate of the bias transistor.

5. The receiver circuit of claim 4, wherein the controller further comprises a second transistor having a gate connected to the power supply voltage, the second transistor being connected to an output of the amplifier.

6. The receiver circuit of claim 2, further comprising a voltage generator configured to generate the power supply voltage.

7. The receiver circuit of claim 6, wherein the voltage generator further comprises at least one current mirror section.

8. The receiver circuit of claim 6, wherein the voltage generator is configured to generate the power supply voltage during a predetermined period.

9. The receiver circuit of claim 1, further comprising:
a logic inverting circuit having an input that receives an output signal from the amplifier; and
a resistor connected in parallel with the logic inverting circuit.

10. The receiver circuit of claim 9, further comprising at least one other logic inverting circuit connected in series with an output of the logic inverting circuit.

11. The receiver circuit of claim 1, wherein the amplifier comprises at least one differential amplifier.

12. The receiver circuit of claim 11, wherein the amplifier comprises:
a first differential amplifier comprising a pair of first-type transistors; and
a second differential amplifier comprising a pair of second-type transistors that are different from the first-type transistors;
wherein the first differential amplifier and the second differential amplifier are connected in parallel.

13. The receiver circuit of claim 11, wherein an input of the at least one differential amplifier receives the input signal and a complementary signal of the input signal.

14. The receiver circuit of claim 13, wherein the amplifier comprises:
a third differential amplifier, wherein the input signal is supplied to a first input terminal of the third differential amplifier and the complementary signal of the input signal is supplied to a second input terminal of the third differential amplifier; and
a fourth differential amplifier, wherein the complementary signal of the input signal is supplied to a first input terminal of the fourth differential amplifier and the input signal is supplied to a second input terminal of the fourth differential amplifier.

15. The receiver circuit of claim 14, further comprising an adjustment circuit configured to control an error in an output timing of respective output signals from the third differential amplifier and the fourth differential amplifier.

16. A semiconductor memory device, comprising the receiver circuit of claim 1.

17. The semiconductor memory device of claim 16, wherein the input signal is any one of a command signal, an address signal, and a clock signal input to the semiconductor memory device.

18. A method for controlling a semiconductor memory device,
wherein the semiconductor memory device includes a receiver circuit comprising an amplifier and a controller, the amplifier being configured to amplify an input signal and to operate according to a bias voltage based on a voltage of the input signal,
the method being executed by the controller and comprising the step of:
preventing the bias voltage from entering a floating state when the input signal having an amplitude exceeding a predetermined value is supplied to the amplifier.
